(19) United States
(12) Patent Application Publication
(10) Pub. No.: US 2014/0230478 A1
(43) Pub. Date: Aug. 21, 2014

(54) COOLING APPARATUS

(71) Applicant: ABB Research Ltd, Zurich (CH)

(72) Inventors: Bruno AGOSTINI, Zurich (CH); Francesco AGOSTINI, Zofingen (CH); Mathieu HABERT, Rheinfelden (CH)

(73) Assignee: ABB Research Ltd, Zurich (CH)

(21) Appl. No.: 14/180,916

(22) Filed: Feb. 14, 2014

(30) Foreign Application Priority Data
Feb. 15, 2013 (EP) 13155414.9

(51) Int. Cl. H05K 7/20

(52) U.S. Cl. CPC H05K 7/20309
USPC 62/259.2

(57) ABSTRACT

A cooling apparatus includes a generator for receiving a first heat load from first electric components, a evaporator for receiving a second heat load from second electric components, a closed compartment enclosing the generator and evaporator, and a third cooling element arranged outside of the closed compartment for receiving heated fluid from at least one of the generator and evaporator and for transferring heat from the heated fluid to outside of the closed compartment. To obtain an efficient and reliable cooling apparatus, a flow channel of the evaporator is configured to receive a fluid in a liquid state and a fluid in a gas state, where the fluid in the gas state reduces a partial pressure of the fluid in a liquid state and the temperature required for evaporating the fluid in the liquid state, such that the fluid in the liquid state is evaporated.

### RELATED APPLICATION

This application claims priority under 35 U.S.C. §119 to European Patent Application No. 13155414.9 filed in Europe on Feb. 15, 2013, the entire content of which is hereby incorporated by reference in its entirety.

### FIELD

The present disclosure relates to a cooling apparatus for cooling electric equipment.

### BACKGROUND INFORMATION

There are known solutions for cooling electric equipment by vaporizing a liquid in a cooling element which is used for transferring heat from electric components into a liquid in a fluid channel of the cooling element. Such a cooling apparatus may work with a dual pressure cycle where the saturation temperature difference between the condenser and the evaporator is produced by a system pressure difference.

A drawback with such known solutions is the need for an mechanical input to drive a compressor or a pump, which generates the required change in pressure.

The need for a compressor or a pump increases the noise level and the costs of the system, while reducing the reliability of the system.

### SUMMARY

An exemplary embodiment of the present disclosure provides a cooling apparatus for electric equipment. The exemplary cooling apparatus includes an evaporator configured to receive a second heat load from second electric components. The evaporator includes a second fluid channel configured to transfer heat received from the second electric components into the second fluid channel. The second fluid channel of the evaporator is configured to receive a fluid in a liquid state and a fluid in a gas state. The fluid in the gas state reduces a partial pressure of the fluid in the liquid state and a temperature required for evaporating the fluid in the liquid state, such that the fluid in the liquid state is evaporated. The exemplary cooling apparatus also includes a closed compartment enclosing the evaporator and the second electric components. In addition, the exemplary cooling apparatus includes a generator configured to receive a first heat load from first electric components having a higher operating temperature than the second electric components. The generator includes a first fluid channel configured to receive liquid and to evaporate a part of the received liquid with the first heat load from the first electric components. The generator and the first electric components are enclosed in the closed compartment. The exemplary cooling apparatus also includes a third cooling element arranged outside of the closed compartment. The third cooling element is configured to receive heated fluid from at least one of the generator and the evaporator, and to transfer heat from the heated fluid to outside of the closed compartment.

### BRIEF DESCRIPTION OF THE DRAWINGS

Additional refinements, advantages and features of the present disclosure are described in more detail below with reference to exemplary embodiments illustrated in the drawings, in which:

FIG. 1 is a block diagram of an exemplary embodiment of a cooling apparatus according to the present disclosure; and

FIG. 2 is a block diagram of an exemplary embodiment of a cooling apparatus according to the present disclosure.

### DETAILED DESCRIPTION

Exemplary embodiments of the present disclosure provide a cooling apparatus for cooling electric equipment, which is simpler, more reliable and cheaper to implement than known techniques.

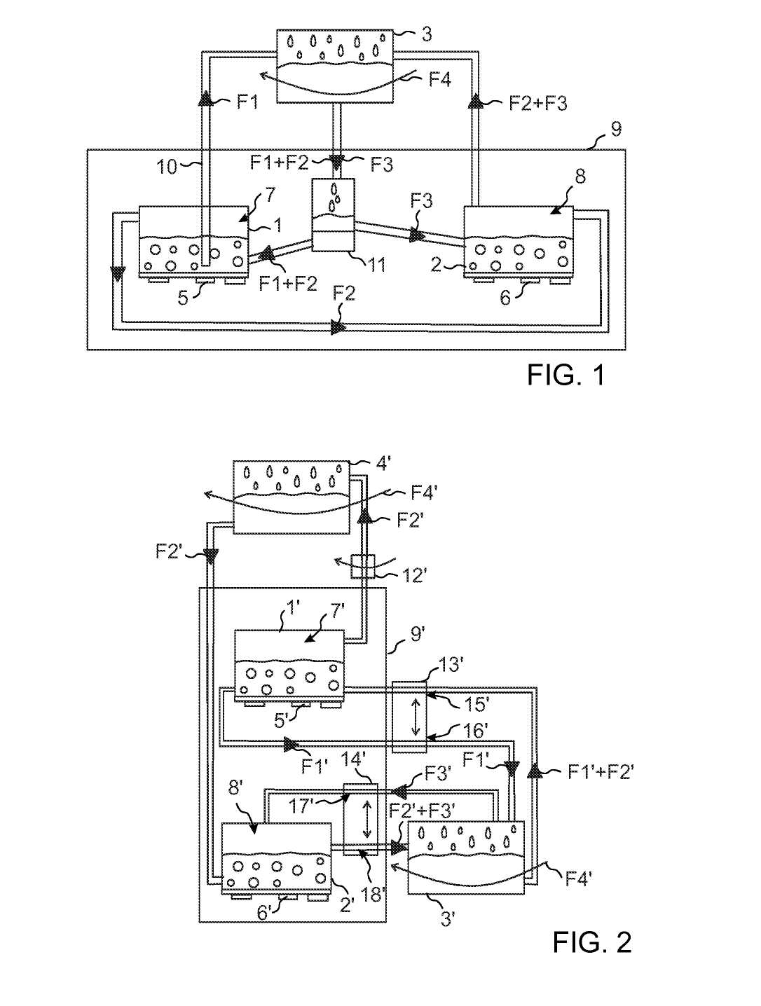

FIG. 1 is a block diagram of an exemplary embodiment of a cooling apparatus according to the present disclosure. The cooling apparatus includes a generator 1 with first electric components 5. The term “generator” refers to a heat exchanger cooling electric components, and which generates heat into the fluid in the fluid channel of the generator by passing on the heat load from the electric components to the fluid. The cooling apparatus also includes an evaporator 2 with second electric components 6. The term “evaporator” refers to a heat exchanger cooling electric components by evaporating fluid in the fluid channel of the evaporator with the heat load from the electric components. In the illustrated exemplary embodiment, it has by way of example been assumed that the first electric components 5 are attached (for example, connected with thermal grease) to the generator 1, and that the second electric components 6 are attached (for example, connected with thermal grease) to the evaporator 2. Consequently, the generator 1 and evaporator 2 may be base plates for accommodating electric components, and the fluid channels are arranged into these base plates (or heat sinks). This is, however, not necessary in all exemplary embodiments. An alternative is that one or both of the generator 1 and evaporator 2 includes fins on an outer surface, and that heat is transferred from the respective electric components to the corresponding cooling element by an airflow and the fins, for example. In any case, heat generated by the first electric components 5 are transferred to a fluid in a flow channel 7 in the generator 1, and correspondingly, heat generated by the second electric components 6 are transferred to a fluid in a flow channel 8 in the evaporator 2.

According to an exemplary embodiment, the first electric components 1 are components with a higher operating temperature than the second electric components 2. The first electric components 1 may include high power electronic devices such as an IGBT (Insulated Gate Bipolar Transistor), a Si/SiC power module (Silicone, Silicone Carbide), an LED (Light Emitting Diode) or other Silicon Carbide electronic components, which may have a high operating temperature, such as about 125° C. at 3 kW, for example. The second electric components 2 may include components with a low operating temperature such as passive electric components like a capacitor, a PCB (Printed Circuit Board) or a surge arrestor, for example. These components may have an operating temperature of about 65° C. at 300 W.

The generator 1 and the evaporator 2 are enclosed in a closed compartment 9. The compartment 9 may be an electrical cabinet sealing off electric devices from the surrounding environment, for example. A high IP class (International Protection) may be required in some applications (such as mining, marine or desert) in order to ensure that dust or moist is efficiently prevented from ending up inside the closed compartment. In order to ensure efficient cooling within such a closed compartment 9, the cooling apparatus includes a third cooling element 3 receiving heated fluid from within the closed compartment 9. This heat is transferred from the fluid to the outside of the closed compartment 9 by the third cooling element 3. Such transfer may include an airstream passing the third cooling element 3, for example.

Three fluids having different properties are circulated within the illustrated cooling apparatus. The first fluid can be water, the second fluid ammonia and the third fluid butane, for example.

The fluid channel 7 of the generator 1 is arranged to receive a first fluid F1 and a second fluid F2 in a liquid state. Heat received from the first electric components 5 is transferred to the fluid in the fluid channel 7. Due to this heat, the second fluid F2, which evaporates at a lower temperature than the first fluid F1, is evaporated while the first fluid F1 remains in a liquid state. The vaporized second fluid F2 in a gas state exits the flow channel 7 via an outlet illustrated in the upper left corner of the generator 1, and enters the flow channel 8 of the evaporator 2 via a pipe. The first fluid F1 enters the third cooling element 3. One alternative to accomplish this while the first fluid F1 remains in the liquid state is that at least a section 10 of the fluid channel 7 of the generator 1 or of a pipe connecting the fluid channel 7 of the generator 1 with the third cooling element 3 includes one or more channels having capillary dimensions. In this context “capillary dimension” refers to channels that are capillary-sized, which means that they have a size small enough for bubbles to grow uniquely in a longitudinal direction (in other words, in the longitudinal direction of the channel as opposed to the radial direction) and thereby create a so-called bubble lift effect by pushing the liquid upwards. The diameter of a channel or tube which is considered capillary depends on the fluid or refrigerant that is used (boiling) inside. The following formula, for example, can be used to evaluate a suitable diameter:

$$D = {( \frac{σ}{g * ( rhol - rhov )} )}^{1 / 2}$$

wherein σ is the surface tension, g the acceleration of gravity, rhov the vapor density and rhol the liquid density. This formula gives a value of around 3 mm for water and ammonia, which are a few examples of the fluids suitable for use as the first fluid F1 in the cooling apparatus. Consequently, the first fluid F1 enters the third cooling element 3 without a need for a pump, for example.

The fluid channel 8 of the evaporator 2 receives the vaporized second fluid F2 in a gas state and the third fluid F3 in a liquid state. The fluids in the fluid channel 8 are heated with heat from the second electric components 2. Additionally, the second fluid F2 in the gas state reduces a partial pressure of the third fluid F3 in a liquid state and therefore also the temperature required for evaporating the third fluid F3. The second fluid F2 and the third fluid F3, both in a vaporized gas state, exit the evaporator 2 and enter the top of third cooling element 3. This flow is obtained due to a thermosyphon effect without a need to utilize a pump.

In the third cooling element 3, the first F1, second F2 and third F3 fluids come into contact with each other, and the fluids are cooled by the third cooling element 3, which transfers heat from the fluids to a medium temperature coolant F4 absorbing the heat from the third cooling element 3. A suitable coolant may be air, water, Carbon Dioxide CO₂, Helium He or Hydrogen H₂, for example. Consequently, heat is transferred to surroundings outside of the closed compartment 9. For this purpose, the third cooling element 3 may have a surface provided with fins, and heat is transferred via the fins to surrounding air, such as into an airflow having a temperature up to 80° C., for example.

As the first fluid F1 and the second fluid F2 have been selected such that they are miscible, the second fluid F2 in a gas state is absorbed by the first fluid F1 which is in the liquid state. This increases the partial pressure of the third fluid F3 being in the gas state, and which has been selected such that it is sparingly miscible or not miscible with the first F1 or second F2 fluid. Consequently, the fluid F3 is condensed in the third cooling element 3.

The mixture of the first F1 and second F2 fluids and the third fluid F3, all in the liquid state, are introduced into a separator 11, which in the illustrated example is located within the closed compartment 9. Due to differences in the density of the mixture of the first F1 and second F2 fluids as compared to the third fluid F3, the separator 11 is able to separate these fluids, such that the mixture of the first F1 and second F2 fluid is forwarded to the flow channel 7 of the generator 1, and the third fluid F3 is forwarded to the flow channel 8 of the evaporator 2.

Circulation of the fluids through the cooling apparatus can, as is clear from the above example, be accomplished without the use of any pumps in the illustrated single pressure absorption cooling system. The energy needed to drive the absorption cycle and the entire cooling process is mainly obtained from the first electric components cooled by the generator 1. Additionally, evaporation of fluid in the evaporator 2 can be obtained even though the heat load from the second electric components 6 may not be sufficient alone to cause such evaporation. Consequently, adequate cooling can also be obtained for the second electric components 6.

In order to ensure efficient circulation of the fluids in all situations, the following relations should apply:

T1>T3>T2, where T1 is the operating temperature of the first electric components 1, T3 is the temperature of the coolant cooling the third cooling element 3, and T2 is the temperature of the second electric components 2,

P3=P1+P2, where P3 is the heat load (power) transferred from the third cooling element 3 via the coolant to the outside of the apparatus, P1 is the heat load generated by the first electric components 5, and P2 is the heat load generated by the second electric components 6, and

P2>>P1 (for example, about 10 times smaller), where P1 is the heat load generated by the first electric components 5, and P2 is the heat load generated by the second electric components 6.

FIG. 2 is a block diagram of an exemplary embodiment of a cooling apparatus according to the present disclosure. The cooling apparatus of FIG. 2 is similar to the one described in connection with FIG. 1. In the following, the exemplary embodiment of FIG. 2 will be described mainly by pointing out the differences between these exemplary embodiments.

In FIG. 2, the cooling apparatus includes a fourth cooling element 4′ arranged outside of the closed compartment 9′ for receiving heated fluid and for transferring heat from the heated fluid to the outside of the closed compartment 9′ via a suitable coolant F4′, such as air, water, Carbon Dioxide CO2, Helium He or Hydrogen H2.

Also the exemplary embodiment of FIG. 2 utilizes three different fluids having different properties. Suitable combinations of fluids are:

water, NH3 and He (or H₂),

### R134a (1,1,1,2-Tetrafluoroethane), DMAC (Dimethylacetamide) and He (or H₂),

### R124 (1-Chloro-1,2,2,2-Tetrafluorethane), DMAC (Dimethylacetamide) and He (or H2),

### R134a (1,1,1,2-Tetrafluoroethane), DMETEG (DiMethyl Ether Tetra Ethylene Glycol) and He (or H₂).

The fluid channel 7′ of the generator 1′ is configured to receive a first fluid F1′ and a second fluid F2′ in a liquid state and to heat the received liquids with heat received from the first electric components 1′. Due to this, the second fluid F2′ is vaporized and forwarded to the fourth cooling 4′ element in a gas state. In the illustrated exemplary embodiment, a rectifier 12′ is arranged between the generator 1′ and the fourth cooling element 4′ to condense back to the generator 1′ any parts of the first fluid F1′ to prevent the first fluid F1′ from reaching (and lowering the performance of) the fourth cooling element 4′. The rectifier 12′ may be implemented as a simple vertical tube exposed to outside air, and which possibly is provided with fins. The first fluid F1′ remaining in a liquid state is forwarded from the generator 1′ to the third cooling element 3′.

The third cooling element 3′ receives the first fluid F1′ in a liquid state from the generator 1′ and the second F2′ and third F3′ fluids in a vaporized gas state from the evaporator 2′. In the third cooling element 3′, the first F1′, second F2′ and third F3′ fluids come into contact with each other and the fluids are cooled by the third cooling element 3′, which transfers heat from the fluids to a medium temperature coolant F4′ absorbing the heat from the third cooling element 3′. A suitable coolant may be air, water, Carbond Dioxide CO2, Helium He or Hydrogen H₂, for example. Consequently, heat is transferred to surroundings outside of the closed compartment 9′. For this purpose, the third cooling element 3′ may have a surface provided with fins, and heat is transferred via the fins to surrounding air, such as into an airflow, for example.

As the first fluid F1′ and the second fluid F2′ have been selected such that they are miscible, the second fluid F2′ in a gas state is absorbed by the first fluid F1′ which is in the liquid state. The mixture of the first F1′ and second F2′ fluids is provided to the generator 1′ from the third cooling element 3′. The third fluid F3′, which has been selected to be sparingly miscible or not miscible with the first F1′ and second fluid F2′, is returned from the third cooling element 3′ to the evaporator 2′ in a vaporized gas state.

The fourth cooling element 4′ receives the vaporized second fluid F2′ in a gas state from the generator 1′. In the fourth cooling element 4′, the second fluid F2′ is cooled such that it condensates, after which it is forwarded to the evaporator 2′ in a liquid state.

The fluid channel 8′ of the evaporator 2′ receives the second fluid F2′ in a liquid state and the third fluid F3′ in a gas state. The fluids in the fluid channel 8′ are heated with heat from the second electric components 2′. Additionally, the third fluid F3′ in the gas state reduces a partial pressure of the second fluid F2′ in a liquid state and therefore also the temperature required for evaporating the second fluid F2′. Therefore, the second fluid F2′ is evaporated in the evaporator 2′. The second fluid F2′ and the third fluid F3′, both in a vaporized gas state, exit the evaporator 2′ and enter the third cooling element 3′.

In the illustrated example, the cooling apparatus of FIG. 2 additionally includes a first heat exchanger 13′ and a second heat exchanger 14′. These heat exchangers are not necessary in all implementations, however, one or more heat exchanger can be utilized in some implementations in order increase the overall performance of the system.

The first heat exchanger 13′ has a first fluid channel 15′ for passing the first F1′ and second F2′ fluids from the third cooling element 3′ to the generator 1′, and a second fluid channel 16′ for passing the first fluid F1′ from the generator 1′ to the third cooling element 3′. Due to the first heat exchanger 13′, the first fluid F1′ from the generator 1′ is pre-cooled before entering the third cooling element 3′.

The second heat exchanger 14′ has a first fluid channel 17′ for passing the third fluid F3′ from the third cooling element 3′ to the evaporator 2′, and a second fluid channel 18′ for passing the second F2′ and third F3′ fluid from the evaporator 2′ to the third cooling element 3′. Due to the second heat exchanger 14′, the second F2′ and third F3′ fluids are pre-cooled before entering the third cooling element 3′.

As in the exemplary embodiments described above, circulation of the fluids through the cooling apparatus can be accomplished without the use of any pumps in the illustrated single pressure absorption cooling system. The energy needed to drive the absorption cycle and the entire cooling process is mainly obtained from the first electric components cooled by the generator 1′. Additionally, evaporation of fluid in the evaporator 2′ can be obtained even though the heat load from the second electric components 6′ may not be sufficient alone to cause such evaporation. Consequently adequate cooling can be obtained also for the second electric components 6′.

In order to ensure efficient circulation of the fluids in all situations the following relations should apply:

T1>T3>T2, where T1 is the operating temperature of the first electric components 1′, T3 is the temperature of the coolant cooling the fourth cooling element 4′ (the temperature of the coolant cooling the third cooling element should also be approximately T3), and T2 is the temperature of the second electric components 2′,

P4+P3+PR=P1+P2, where P3 and P4, respectively are the heat loads (power) transferred from the third 3′ respective fourth 4′ cooling elements via the coolant F4′ to the outside of the apparatus, P1 is the heat load generated by the first electric components 5′, P2 is the heat load generated by the second electric components 6′, and PR the heat exchanged in the rectifier 12′.

P2>>P1 (for example, about 5 to 10 times smaller), where P1 is the heat load generated by the first electric components 5′, and P2 is the heat load generated by the second electric components 6′.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

What is claimed is:

1. A cooling apparatus for electric equipment comprising:
an evaporator configured to receive a second heat load from second electric components, the evaporator comprising a second fluid channel configured to transfer heat received from the second electric components into the second fluid channel, the second fluid channel of the evaporator being configured to receive a fluid in a liquid state and a fluid in a gas state, the fluid in the gas state reducing a partial pressure of the fluid in the liquid state and a temperature required for evaporating the fluid in the liquid state, such that the fluid in the liquid state is evaporated;
a closed compartment enclosing the evaporator and the second electric components;
a generator configured to receive a first heat load from first electric components having a higher operating temperature than the second electric components, the generator comprising a first fluid channel configured to receive liquid and to evaporate a part of the received liquid with the first heat load from the first electric components, the generator and the first electric components being enclosed in the closed compartment; and
a third cooling element arranged outside of the closed compartment and configured to receive heated fluid from at least one of the generator and the evaporator, and to transfer heat from the heated fluid to outside of the closed compartment.

2. A cooling apparatus according to claim 1, wherein the first electric components include power electronic devices generating a higher heat load than the second electric components which include passive electric components.

3. A cooling apparatus according to claim 1, wherein the cooling apparatus contains three different fluids:
a first fluid and a second fluid which are miscible; and
a third fluid which is one of sparingly miscible and not miscible with the first or second fluids.

4. A cooling apparatus according to claim 1, wherein:
the first fluid channel of the generator is configured to receive a first fluid and a second fluid in a liquid state, to heat the received first and second liquids with heat received from the first electric components, to provide the third cooling element with the first fluid in a liquid state, and to provide the second fluid channel of the evaporator with the vaporized second fluid in a gas state;
the second fluid channel of the evaporator is configured to receive the vaporized second fluid in a gas state from the generator and to receive a third fluid in a liquid state, to heat the received second and third fluids with heat from the second electric components to vaporize the second and third fluids, and to provide the third cooling element with the vaporized second and third fluids in a gas state; and
the third cooling element is configured to receive the first fluid in a liquid state from the generator and the vaporized second and third fluids in a gas state from the evaporator, to absorb the vaporized second fluid by the first fluid in a liquid state to obtain a liquid of the miscible first and second fluids and to condense the third fluid, which is one of sparingly miscible and not miscible with the first fluid, into a liquid while transferring heat from the first to third fluids to the outside of the closed compartment, and to provide the generator via a separator with the first and second fluids in a liquid state and the evaporator with the third fluid in a liquid state.

5. A cooling apparatus according to claim 4, wherein at least a section of one of the first fluid channel of the generator and of a pipe connecting the fluid first channel of the generator with the third cooling element includes one or more channels having a capillary dimension.

6. A cooling apparatus according to claim 1, wherein:
the cooling apparatus comprises a fourth cooling element arranged outside of the closed compartment, the fourth cooling element being configured to receive heated fluid and to transfer heat from the heated fluid to the outside of the closed compartment;
the first fluid channel of the generator is configured to receive the first fluid and the second fluid in a liquid state, to heat the received first and second liquids with heat received from the first electric components to vaporize the second liquid, to provide the fourth cooling element with the vaporized second fluid in a gas state, and to provide the third cooling element with the first fluid in a liquid state,
the third cooling element is configured to receive the first fluid in a liquid state from the generator, the second fluid and a third fluid in a vaporized gas state from the evaporator, to absorb the vaporized second fluid by the first fluid in a liquid state to obtain a liquid of the miscible first and second fluids while transferring heat from the fluids to the outside of the closed compartment, to provide the first fluid channel of the generator with the first and second fluids in a liquid state, and to provide the evaporator with the third fluid, which is one of sparingly miscible and not miscible with the first and second fluids, in a vaporized gas state; and
the fourth cooling element is configured to receive the vaporized second fluid in a gas state from the generator, to condense the second fluid, and to provide the second fluid in a liquid state to the evaporator.

7. A cooling apparatus according to claim 6, comprising:
a first heat exchanger including a third fluid channel configured to pass the first and second fluids from the third cooling element to the generator, and a fourth fluid channel configured to pass the first fluid from the generator to the third cooling element.

8. A cooling apparatus according to claim 6, comprising:
a second heat exchanger including a fifth fluid channel configured to pass the third fluid from the third cooling element to the evaporator, and a sixth fluid channel configured to pass the second and third fluids from the evaporator to the third cooling element.

9. A cooling apparatus according to claim 7, comprising:
a second heat exchanger including a fifth fluid channel configured to pass the third fluid from the third cooling element to the evaporator, and a sixth fluid channel configured to pass the second and third fluids from the evaporator to the third cooling element.
